(19) United States
(12) Patent Application Publication
(10) Pub. No.: US 2011/0128044 A1
(43) Pub. Date: Jun. 2, 2011

(54) TEST APPARATUS, TEST METHOD, AND PHASE SHIFTER

(75) Inventor: Kenji TAMURA, Gunma (JP)

(73) Assignee: ADVANTEST CORPORATION, Tokyo (JP)

(21) Appl. No.: 12/980,292

(22) Filed: Dec. 28, 2010

Related U.S. Application Data
(63) Continuation of application No. PCT/JP2009/003209, filed on Jul. 9, 2009.

(30) Foreign Application Priority Data
Jul. 9, 2008 (JP) 2008-179165

(51) Int. Cl. H03D 13/00

(52) U.S. Cl. 327/5

(57) ABSTRACT

A test apparatus includes a recovered clock generating circuit generating a recovered clock having substantially the same phase as an output of a device under test (DUT), a data acquiring section acquiring a value of the output data at a timing indicated by a strobe signal based on the recovered clock, a comparator comparing the value acquired by the data acquiring section to a prescribed expected value, and a judging section judging pass/fail of the DUT based on a comparison result. The recovered clock generating circuit includes a phase comparator comparing the phase of the output data of the DUT to the phase of the recovered clock, a control signal generating section generating a control signal such that the phase of the recovered clock is synchronized with the phase of the output data, and a phase shifter continuously shifting the phase of the reference clock based on the control signal.

### BACKGROUND

1. Technical Field

The present invention relates to a test apparatus, a test method and a phase shifter. The present invention relates to, in particular, a test apparatus, a test method and a phase shifter that can reduce differential nonlinearity (DNL).

2. Related Art

Japanese Patent Application Publication 2005-285160 (Patent Document 1) is an example of related art.

Patent Document 1 discloses a test apparatus in which output data from a device under test is synchronized with a recovered clock, in order to make a strobe signal that is based on the recovered clock follow a timing variation in the output data of the device under test.

However, when clock recovery is performed by using a phase-locked loop (PLL), the test apparatus is subjected to following drawbacks. In actual specifications, it is preferable that loop latency be under several ns. However, a bandwidth of an active low-pass filter is limited to a few MHz at most and this causes a phase delay of several dozen of ns. Moreover, increase in the loop latency reduces a timing margin on a timing comparator, resulting in degradation in a jitter tolerance.

Furthermore, PLLs have a limited phase shifting range and therefore a tracking range is limited. When wish to advance the phase beyond the phase shifting range, the phase has to be once returned to a prescribed phase position at a period of a strobe signal. By doing this, the phase becomes unstable during the phase is returned to the prescribed position. As a result, it becomes impossible to determine pass/fail of the device under test. Consequently, devices under test cannot be accurately tested.

### SUMMARY

Therefore, it is an object of an aspect of the innovations herein to provide a test apparatus, a test method and a phase shifter, which are capable of overcoming the above drawbacks accompanying the related art. The above and other objects can be achieved by combinations described in the claims. According to a first aspect of the innovations, a test apparatus that tests a device under test may include a reference clock source that generates a reference clock for controlling operations of the device under test, a recovered clock generating circuit that generates a recovered clock having substantially the same phase as a phase of output data output by the device under test, a data acquiring section that acquires an output value of the output data at a timing indicated by a strobe signal that is based on the recovered clock, a comparator that compares the output value acquired by the data acquiring section to a prescribed expected value, and a judging section that judges pass or fail of the device under test based on a comparison result made by the comparator. The recovered clock generating circuit includes a phase comparator that compares the phase of the output data output by the device under test to the phase of the recovered clock, a control signal generating section that generates a control signal such that the phase of the recovered clock is synchronized with the phase of the output data, and a phase shifter that continuously shifts the phase of the reference clock based on the control signal. The test apparatus that tests a device under test may include a reference clock source that generates a reference clock for controlling operations of the device under test, a recovered clock generating circuit that generates a recovered clock having substantially the same phase as a phase of output data output by the device under test, a data acquiring section that acquires an output value of the output data at a timing indicated by a strobe signal that is based on the recovered clock, a comparator that compares the output value acquired by the data acquiring section to a prescribed expected value, and a judging section that judges pass or fail of the device under test based on a comparison result made by the comparator. The recovered clock generating circuit may include a phase comparator that compares the phase of the output data output by the device under test to the phase of the recovered clock, and a phase shifter that continuously shifts the phase of the reference clock based on an output of the phase comparator.

The control signal generating section may generate a first control voltage and a second control voltage as the control signal. The phase shifter may includes a phase shifter that shifts the phase of the reference clock by a prescribed angular degree, a first multiplier that multiplies the reference clock by the first control voltage, a second multiplier that multiplies an output of the phase shifter by the second control voltage, and an adding section that adds an output of the first multiplier to an output of the second multiplier. Alternatively, the test apparatus may further include a control signal generating section that generates a control signal based on the output of the phase comparator such that the phase of the recovered clock is synchronized with the phase of the output data, the control signal generating section generates a first control voltage and a second control voltage as the control signal. The phase shifter includes a phase shifter that shifts the phase of the reference clock by a prescribed angular degree, a first multiplier that multiplies the reference clock by the first control voltage, a second multiplier that multiplies an output of the phase shifter by the second control voltage, and an adding section that adds an output of the first multiplier to an output of the second multiplier.

The phase shifter may shift the phase of the reference clock by approximately 90°. The phase shifter may further include a low-pass filter that removes a high-frequency wave included in the output of the adding section. The phase shifter may further includes a frequency divider that divides a frequency of the output from the adding section. The test apparatus may further include a frequency divider that divides a frequency of the recovered clock output by the recovered clock generating circuit. And the data acquiring section acquires the output value of the output data at a timing indicated by a strobe signal that is based on the recovered clock of which frequency is divided by the frequency divider.

A second aspect of the innovations may provide a test method for testing a device under test. The test method includes: (a) generating a reference clock for controlling operations of the device under test with a reference frequency; (b) generating a recovered clock that has substantially the same phase as a phase of output data output by the device under test; (c) acquiring an output value of the output data at a timing indicated by a strobe signal that is based on the recovered clock; (d) comparing the output value acquired in the acquiring step (c) to a prescribed expected value; and (e) judging pass or fail of the device under test based on a comparison result made in the comparing step (d). The generating step (b) includes: (f) comparing the phase of the output data output by the device under test to the phase of the recovered clock; (h) generating a control signal, based on an output of the comparing step (f), such that the phase of the recovered clock is synchronized with the phase of the output data; and (g) shifting the phase of the reference clock continuously based on a comparison result made in the comparing step (f). Alternatively, the test method for testing a device under test may includes: (a) generating a reference clock for controlling operations of the device under test with a reference frequency; (b) generating a recovered clock that has substantially the same phase as a phase of output data output by the device under test; (c) acquiring an output value of the output data at a timing indicated by a strobe signal that is based on the recovered clock; (d) comparing the output value acquired in the acquiring step (c) to a prescribed expected value; and (e) judging pass or fail of the device under test based on a comparison result made in the comparing step (d). The generating step (b) may include: (f) comparing the phase of the output data output by the device under test to the phase of the recovered clock; and (g) shifting the phase of the reference clock continuously based on a comparison result made in the comparing step (f).

The test method may further include (h) generating a control signal, based on an output of the comparing step (f), such that the phase of the recovered clock is synchronized with the phase of the output data, a first control voltage and a second control voltage are generated as the control signal. The shifting step (g) may include: (i) shifting the phase of the reference clock by a prescribed angular degree; (j) multiplying the reference clock by the first control voltage; (k) multiplying an output of the shifting step (i) by the second control voltage; and (l) adding an output of the multiplying step (j) to an output of the multiplying step (k). In the second aspect of the innovations, the phase of the reference clock may be shifted by approximately 90° in the shifting step (i). The shifting step (g) may further include (m) low-pass filtering an output of the adding step (l) to remove a high-frequency wave included therein. The shifting step (g) may further include (n) dividing a frequency of an output of the adding step (l). The test method may further include (o) dividing a frequency of the recovered clock of the generating step (b). In the acquiring step (c), the output value of the output data may be acquired at a timing indicated by a strobe signal that is based on the recovered clock of which frequency is divided in the dividing step (o).

A third aspect of the innovations may provide a phase shifter including a phase shifting section to which an alternate current input signal is supplied, and that shifts a phase of the input signal by a prescribed angular degree, a first multiplying section to which the input signal and a first control voltage are supplied, and that multiplies the input signal by the first control voltage, a second multiplying section to which an output signal of the phase shifting section and a second control voltage are supplied, and that multiplies the output signal of the phase shifting section by the second control voltage, and an adding section to which output signals of the first multiplying section and the second multiplying section are supplied, and that adds the output signal of the first multiplying section to the output signal of the second first multiplying section. The phase of the input signal is sequentially shifted with the first control voltage and the second control voltage.

In the third aspect of the innovations, the phase shifting section may shift the phase of the input signal by approximately 90°. The phase shifter may further include a low-pass filter that removes a high-frequency wave included in the output of the adding section.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates a configuration of a phase shifter 101 using an IQ modulator according to a first embodiment of the invention.

FIG. 2 illustrates an example of signal waveforms of signals output by the reference clock and the phase shifter 101.

FIG. 3 illustrates a relation between a first control voltage and a second control voltage and a phase shift angular degree.

FIG. 4 illustrates a configuration example of a test apparatus 110 according to a second embodiment of the invention.

FIG. 5 illustrates a relationship between the first control voltage and the second voltage and a tracking range.

FIG. 6 is a block diagram of the test apparatus 110 in which a frequency divider is provided in the phase shifter 101.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

### First Embodiment

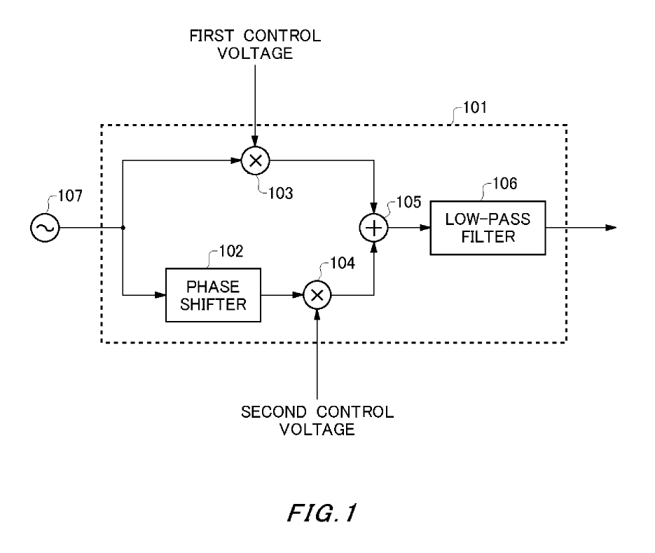

FIG. 1 illustrates a configuration of a phase shifter 101 using an IQ modulator according to a first embodiment of the invention. The phase shifter 101 includes a phase shifter 102, a first multiplier 103, a second multiplier 104, an adder 105 and a low-pass filter 106.

A reference clock source 107 from which a signal waveform is supplied to the phase shifter 101 is also shown in FIG. 1. The reference clock source 107 generates an alternate current signal. This alternate current signal generated by the reference clock source 107 is referred as to a reference clock. A frequency of this reference clock is set as a reference frequency. The reference clock source 107 outputs the generated reference clock to the phase shifter 102 and the first multiplier 103.

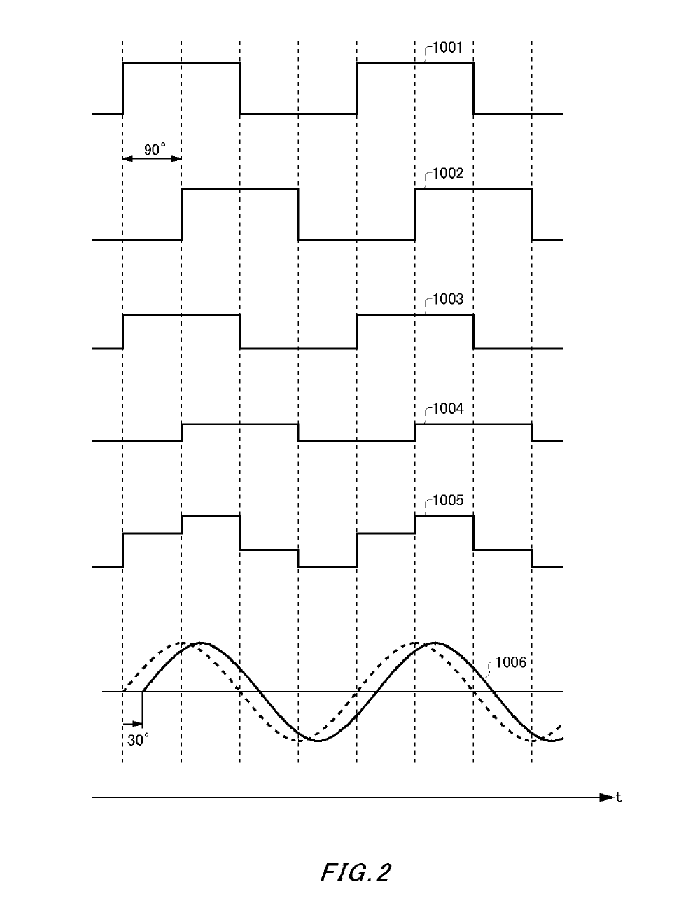

FIG. 2 illustrates an example of signal waveforms of signals output by the reference clock and the phase shifter 101. Referring to FIG. 2, a signal waveform pattern 1001 shows a waveform of the reference clock output by the reference clock source 107. The reference clock is not necessarily a square wave.

The phase shifter 102 shifts a phase of the reference clock supplied thereto by 90°. The phase shifter 102 then outputs a 90°-phase-shifted reference clock to the second multiplier 104. Referring again to FIG. 2, a signal waveform pattern 1002 shows a waveform of a signal output by the phase shifter 102. The signal waveform pattern 1002 shows that the signal is delayed by 90° from the reference clock waveform or the phase of the signal waveform pattern 1001. A phase shift by the phase shifter 102 is not limited to 90° but may be any prescribed angular degree. Moreover, the phase shifter 102 may shift phases by approximately 90°.

The reference clock generated by the reference clock source 107, and a first control voltage are supplied to the first multiplier 103. The first multiplier 103 multiplies the reference clock input thereto by the first control voltage. By multiplying the reference clock by the first control voltage, an amplitude of the reference clock can be changed. The first multiplier 103 outputs the multiplied signal to the adder 105.

Referring to FIG. 2, a signal waveform pattern 1003 shows a waveform of a signal output by the first multiplier 103. It can be seen from the drawing that the signal waveform pattern 1003 has the same phase as the signal waveform pattern 1001 but has a different amplitude. As shown in FIG. 2, the amplitude of the signal waveform pattern 1003 is smaller than the amplitude of the signal waveform pattern 1001.

The reference clock of which phase is shifted by 90° by the phase shifter 102, and a second control voltage are supplied to the second multiplier 104. The second multiplier 104 multiplies the 90°-phase-shifted reference clock input thereto by the second control voltage. By multiplying the 90°-phase-shifted reference clock by the second control voltage, an amplitude of the 90°-phase-shifted reference clock can be changed. The second multiplier 104 outputs the multiplied signal to the adder 105.

Referring to FIG. 2, a signal waveform pattern 1004 shows a waveform of a signal output by the second multiplier 104. It is understood from the drawing that the signal waveform pattern 1004 has the same phase as the signal waveform pattern 1002, which is the waveform of the signal output by the phase shifter 102, but has a different amplitude. Referring again to FIG. 2, the amplitude of the signal waveform pattern 1004 is smaller than the amplitude of the signal waveform pattern 1002.

The adder 105 adds the signal output by the first multiplier 103 to the signal output by the second multiplier 104. The adder 105 outputs the added signal to the low-pass filter 106. Referring to FIG. 2, a signal waveform pattern 1005 shows a waveform of the signal output by the adder 105. It can be understood from the drawing that the signal waveform pattern 1005 is a waveform pattern generated by adding the signal waveform pattern 1003 and the signal waveform pattern 1004.

The low-pass filter 106 may be a passive filter which removes high-frequency wave in the clock frequency. With such low-pass filter, a cut-off frequency becomes over several GHz. The low-pass filter removes the high frequency of the signal input by the adder 105, and outputs a filtered signal. Referring to FIG. 2, a signal waveform pattern 1006 shows a waveform of the signal output by the low-pass filter 106. It can tell from the drawing that the signal waveform pattern 1006 has a waveform after the high frequency is removed from the signal waveform pattern 1005 which is output by the adder 105.

In FIG. 2, the waveform drawn with a dashed line shows the phase of the reference clock. A phase of the signal waveform pattern 1006 is delayed from the phase of the reference clock by 30°. This phase shift value of the reference clock can be changed by adjusting levels of the first and second control voltages supplied to the first multiplier 103 and the second multiplier 104 respectively.

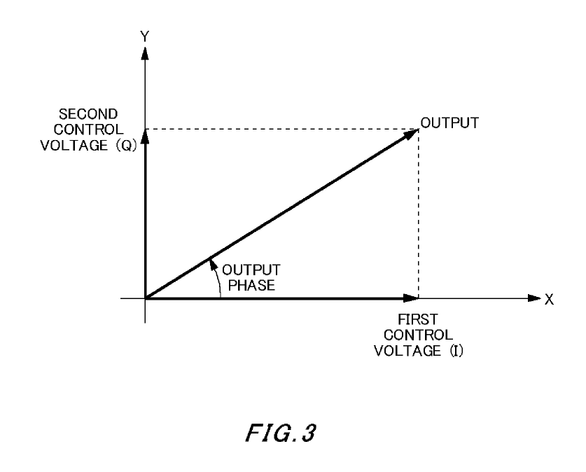

FIG. 3 illustrates a relation between the first control voltage and a second control voltage and a phase shift angular degree. The x-axis is the first control voltage (I side), and the y-axis is the second control voltage (Q side). The reason why the second control voltage is on the y-axis is that the second control voltage is multiplied by the 90°-phase-shifted reference clock.

An angle between the x-axis and a line that connects the origin (0, 0) and a point designated by the values of the first control voltage and the second control voltage represents the angular degree of the phase shift. In other words, this angle represents a phase output by the phase shifter 101. This phase shift is determined depending on the values of the first control voltage and the second control voltage. In this way, phase shifts can be set to any value by changing the values of the first control voltage and the second control voltage. In other words, phase can be shifted by any angular degrees from 0° to 360°.

Phases are conventionally shifted by using a multistage delay buffer so that a noise floor is deteriorated, and resulting in increase in random jitter. As a result, error in linearity of the delay time is increased. Moreover, conventionally, a multiplexer selects one of delay signals delayed by a multistage delay buffer, and then outputs the selected delayed signal. In this way, differential nonlinearity (DNL) can become large depending on a length of the path through which the selected delayed signal passes, and the DNL is deteriorated as the delay amount increases. Consequently, error in the linearity of the delay time becomes quite large.

Unlike the above-mentioned conventional configuration, according to the phase shifter 101 of the first embodiment, a clock signal of which phase to be shifted is input into the phase shifter 102, two signals which are orthogonal to each other are then generated, amplitudes of the two signals are changed depending on the values of the first control voltage and the second control voltage, and the two signals are subsequently combined. In this way, the clock signal can be shifted to a desired phase in a continuous manner. Furthermore, the phase shift amount can be set to any angular degrees from 0° to 360°. Moreover, since the linearity of the first control voltage and the second control voltage can be easily improved compared to the linearity of the delay time, it is possible to reduce the error in the linearity as a consequence.

### Second Embodiment

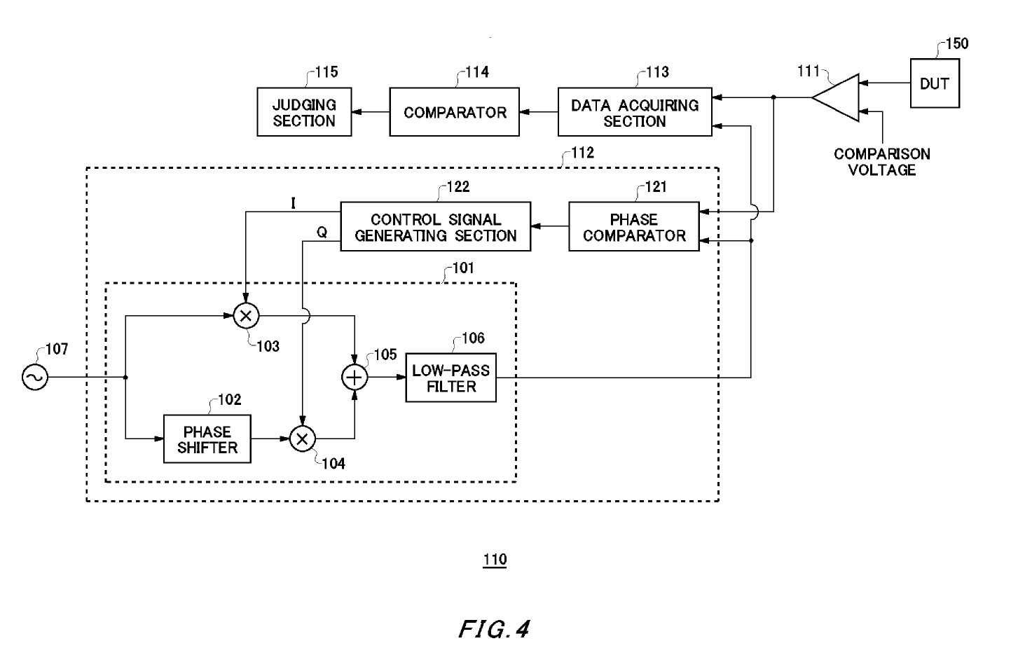

FIG. 4 illustrates a configuration example of a test apparatus 110 according to a second embodiment of the invention. The same reference numerals are given to the same structures or components as the first embodiment. The test apparatus 110 includes by the reference clock source 107, a level comparator 111, a recovered clock generating circuit 112, a data acquiring section 113, a comparator 114 and a judging section 115.

A reference clock generated by the reference clock source 107 is used for controlling operations of a device under test (DUT) 150. In other words, the reference clock source 107 generates the reference clock which controls operations of the DUT 150. The DUT 150 operates based on the reference clock generated by the reference clock source 107, and outputs output data.

The level comparator 111 compares the output data output by the DUT 150 to a prescribed comparison voltage, and generates a binary output data. The level comparator 111 then supplies the generated output data to a phase comparator 121 in the recovered clock generating circuit 112, and to the data acquiring section 113.

The recovered clock generating circuit 112 generates, based on the reference clock generated by the reference clock source 107, a recovered clock of which frequency is substantially the same as the reference frequency of the reference clock and of which phase is substantially the same as a phase of the output data. The recovered clock generating circuit 112 then outputs the generated recovered clock to the data acquiring section 113.

The data acquiring section 113 acquires an output value of the output data from the DUT 150 at a timing indicated by a strobe signal based on the received recovered clock. The data acquiring section 113 then outputs the obtained output value to the comparator 114. The data acquiring section 113 may be a timing comparator.

The strobe signal based on the recovered clock may be a signal which is generated by delaying the phase of the recovered clock. Alternatively, the strobe signal may be the recovered clock as it is. When the strobe signal is the recovered clock of which phase is delayed, a delaying circuit may be provided in the data acquiring section 113, and the delaying circuit may generate the strobe signal from the recovered clock. Alternatively, a delaying circuit may be provided between the data acquiring section 113 and the recovered clock generating circuit 112, this delaying circuit may generate the strobe signal from the recovered clock and may output it to the data acquiring section 113.

The comparator 114 compares the output value sent from the data acquiring section 113 to a prescribed expected value, and outputs fail data or pass data to the judging section 115. The judging section 115 judges pass or fail of the DUT 150 based on the comparison result of the comparator 114. The comparator 114 may acquire the expected value from the outside and may compare the output value to the acquired expected value.

The recovered clock generating circuit 112 will be now described. The recovered clock generating circuit 112 includes the phase shifter 101, the phase comparator 121 and a control signal generating section 122. In the second embodiment, a signal output by the phase shifter 101 is referred as to the recovered clock. In other words, the phase shifter 101 generates the recovered clock.

Output data output by the level comparator 111 and the recovered clock output by the phase shifter 101 are supplied to the phase comparator 121. The phase comparator 121 compares the phase of the output data supplied thereto with the phase of the recovered clock. The phase comparator 121 then outputs a phase difference therebetween as a comparison result to the control signal generating section 122.

The control signal generating section 122 generates a control signal based on the comparison result output by the phase comparator 121. The control signal is for synchronizing the phase of the recovered clock with the phase of the output data. The control signal generating section 122 outputs the generated control signal to the phase shifter 101. The control signal generating section 122 generates a first control voltage and a second control voltage as the control signal. The control signal generating section 122 supplies the first control voltage to the first multiplier 103 of the phase shifter 101, and supplies the second control voltage to the second multiplier 104 of the phase shifter 101.

The phase shifter 101 generates the recovered clock by continuously shifting the phase of the reference clock based on the control signal output by the control signal generating section 122. More specifically, the first multiplier 103 of the phase shifter 101 multiplies the first control voltage and the reference clock to output the resulting signal to the adder 105. The second multiplier 104 multiplies the second control voltage supplied thereto by the reference clock of which phase is shifted by 90°, and outputs the resulting signal to the adder 105.

The adder 105 adds the signals supplied thereto, and then outputs the resulting signal to the low-pass filter 106. The low-pass filter 106 cuts high frequency wave and outputs the resulting signal. The signal output by the low-pass filter 106 is supplied to the data acquiring section 113 and the phase comparator 121 as the recovered clock.

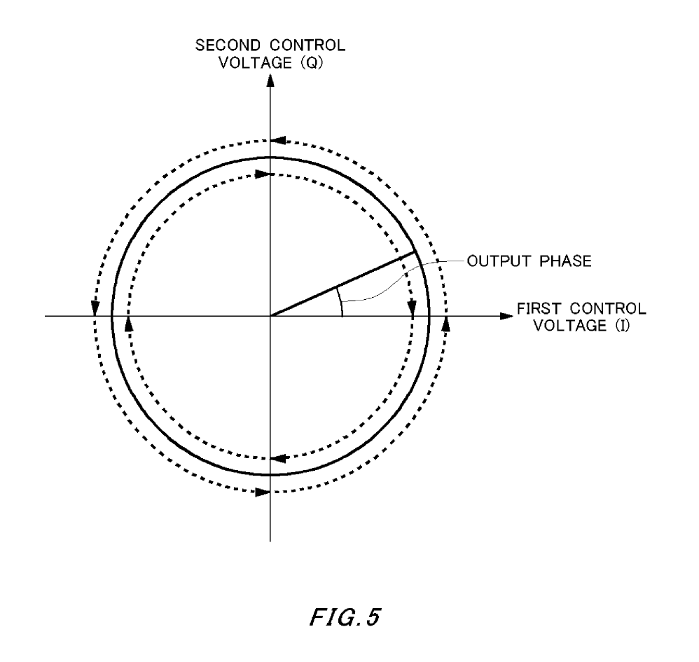

FIG. 5 illustrates a relationship between the first control voltage and the second voltage and a tracking range. The x-axis is the first control voltage (I side), and the y-axis is the second control voltage (Q side). The reason why the second control voltage is on the y-axis is that the second control voltage is multiplied by the 90°-phase-shifted reference clock. An angle defined by the first control voltage and the second control voltage is an angular degree of the phase shift, which is the phase value output by the phase shifter 101. Referring to FIG. 5, by changing values of the first control voltage and the second control voltage, it is possible to keep rotating the phase without making discontinuous points, allowing the tracking range to be infinite.

In this way, the phase comparator 121 compares the phase of the output data by the DUT 150 to the phase of the recovered clock. The control signal generating section 122 generates the first control voltage and the second control voltage such that the phase of the output data is synchronized with the phase of the recovered clock, and outputs the first and second voltages to the first multiplier 103 and the second multiplier 104 respectively. In this way, the phase shifter 101 can generate the recovered clock of which phase is precisely synchronized with the phase of the output data, and thereby it is possible for the recovered clock and the strobe signal to follow the timing variation of the output data output by the DUT 150. As a result, it is possible to test the device under test accurately.

A phase delay at the IQ modulator is in a range of several dozen of ps, and this IQ modulator is used for clock recovery and thereby it is possible to reduce the loop latency. Moreover, by adopting the IQ modulator, a low-pass filter with a cut-off frequency of more than several GHz can be used. Consequently, the phase delay becomes several dozen of ps, and thereby it is possible to reduce the loop latency. In addition, the timing margin at the data acquiring section 113 becomes smaller, and thereby it is possible to arrest the degradation in the jitter tolerance. Moreover, it is possible to make the tracking range infinite by using the IQ modulator. In this way, it is possible to improve the testing performance of the test apparatus.

The above described second embodiment can be modified to the flowing configurations hereunder described.

(1) Although the reference clock generated by one reference clock source 107 is supplied to the phase shifter 101, and the operation of the DUT 150 is controlled by using the reference clock in the above-described embodiment, another reference clock source that separately generates a reference clock for controlling the operation of the DUT 150 may be provided in addition to the clock source that generate the reference clock supplied to the phase shifter.

(2) In the above modification example (1), a frequency of the reference clock supplied to the phase shifter 101 may not be same as the frequency of the reference clock for controlling the operation of the DUT 150. Alternatively, the frequency of the reference clock supplied to the phase shifter 101 may be substantially the same as the frequency of the reference clock for controlling the operation of the DUT 150.

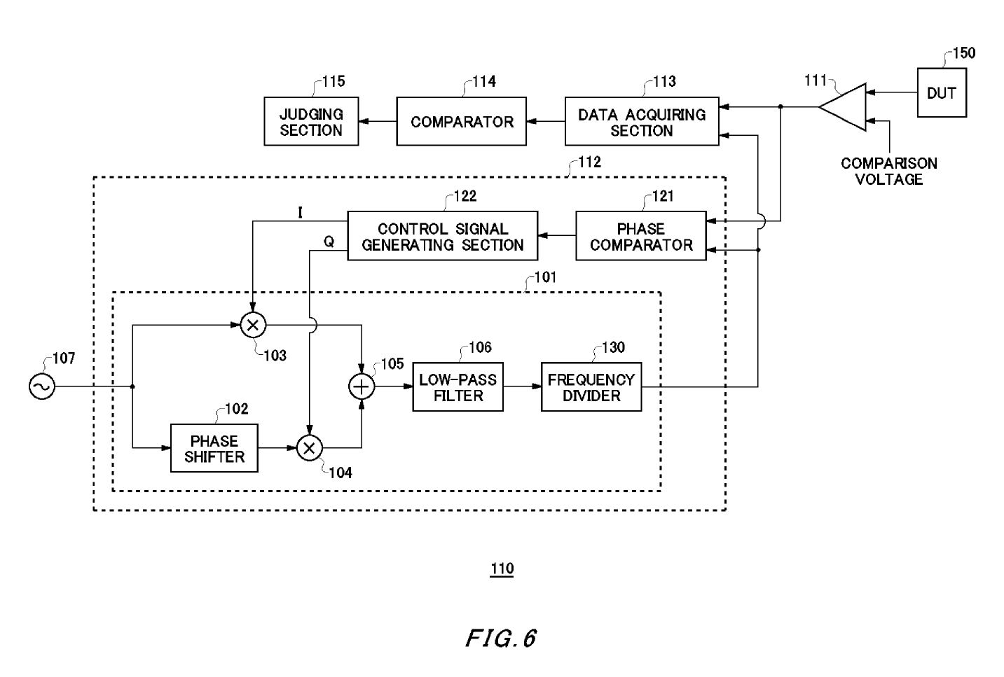

(3) A frequency divider may be provided after the low-pass filter 106. FIG. 6 is a block diagram of the test apparatus 110 in which a frequency divider is provided in the phase shifter 101. In this case, a signal output by a frequency divider 130 is referred as to the recovered clock. The frequency divider 130 outputs the recovered clock to the data acquiring section 113 and the phase comparator 121.

Alternatively, the frequency divider 130 may be provided outside the recovered clock generating circuit 112. In this case, the recovered clock generating circuit 112 outputs the recovered clock to the phase comparator 121 and the frequency divider 130, and the frequency divider supplies the divided recovered clock to the data acquiring section 113.

In this way, it is possible to make the frequency of the reference clock supplied to the phase shifter 101 differ from the frequency of the reference clock for controlling the operation of the DUT 150 depending on the frequency division by the frequency divider 130. For example, when a frequency is made 1/N times a frequency by the frequency divider 130, the frequency of the reference clock for controlling the operation of the DUT can be made to 1/N times the frequency of the reference clock supplied to the phase shifter 101, where N may be a positive integer.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test, comprising:
a reference clock source that generates a reference clock for controlling operations of the device under test;
a recovered clock generating circuit that generates a recovered clock having substantially the same phase as a phase of output data output by the device under test;
a data acquiring section that acquires an output value of the output data at a timing indicated by a strobe signal that is based on the recovered clock;
a comparator that compares the output value acquired by the data acquiring section to a prescribed expected value; and
a judging section that judges pass or fail of the device under test based on a comparison result made by the comparator;
wherein the recovered clock generating circuit continuously shifts a phase of the reference clock based on a result of comparison between the phase of the output data output by the device under test and a phase of the recovered clock.

2. The test apparatus according to claim 1, wherein the recovered clock generating circuit includes:
a phase comparator that compares the phase of the output data output by the device under test to the phase of the recovered clock; and
a phase shifter that continuously shifts the phase of the reference clock based on an output of the phase comparator.

3. The test apparatus according to claim 2, further comprising:
a control signal generating section that generates a control signal based on the output of the phase comparator such that the phase of the recovered clock is synchronized with the phase of the output data, the control signal generating section generating a first control voltage and a second control voltage as the control signal,
wherein the phase shifter includes:
a phase shifter that shifts the phase of the reference clock by a prescribed angular degree;
a first multiplier that multiplies the reference clock by the first control voltage;
a second multiplier that multiplies an output of the phase shifter by the second control voltage; and
an adding section that adds an output of the first multiplier to an output of the second multiplier.

4. The test apparatus according to claim 3, wherein
the phase shifter shifts the phase of the reference clock by approximately 90°.

5. The test apparatus according to claim 3, wherein
the phase shifter further includes:
a low-pass filter that removes a high-frequency wave included in the output of the adding section.

6. The test apparatus according to claim 3, wherein
the phase shifter further includes:
a frequency divider that divides a frequency of the output from the adding section.

7. The test apparatus according to claim 3, further comprising:
a frequency divider that divides a frequency of the recovered clock output by the recovered clock generating circuit,
wherein the data acquiring section acquires the output value of the output data at a timing indicated by a strobe signal that is based on the recovered clock of which frequency is divided by the frequency divider.

8. A test method for testing a device under test, comprising:
(a) generating a reference clock that has a reference frequency, and that is for controlling operations of the device under test;
(b) generating a recovered clock that has substantially the same phase as a phase of output data output by the device under test;
(c) acquiring an output value of the output data at a timing indicated by a strobe signal that is based on the recovered clock;
(d) comparing the output value acquired in the acquiring (c) to a prescribed expected value; and
(e) judging pass or fail of the device under test based on a comparison result made in the comparing (d),
wherein the generating (b) includes:
(f) comparing the phase of the output data output by the device under test to the phase of the recovered clock; and
(g) shifting the phase of the reference clock continuously based on a comparison result made in the comparing (f).

9. The test method according to claim 8, further comprising:
(h) generating a control signal, based on an output of the comparing (f), such that the phase of the recovered clock is synchronized with the phase of the output data, wherein a first control voltage and a second control voltage are generated as the control signal,
wherein the shifting (g) includes:
(i) shifting the phase of the reference clock by a prescribed angular degree;
(j) multiplying the reference clock by the first control voltage;
(k) multiplying an output of the shifting (i) by the second control voltage; and
(l) adding an output of the multiplying (j) to an output of the multiplying (k).

10. The test method according to claim 9, wherein the phase of the reference clock is shifted by approximately 90° in the shifting step (i).

11. The test method according to claim 9, wherein the shifting step (g) further includes:
(m) low-pass filtering an output of the adding (l) to remove a high-frequency wave included therein.

12. The test method according to claim 9, wherein the shifting (g) further includes:
(n) dividing a frequency of an output of the adding step (l).

13. The test method according to claim 9, further comprising:
(o) dividing a frequency of the recovered clock of the generating step (b),
wherein in the acquiring (c), the output value of the output data is acquired at a timing indicated by a strobe signal that is based on the recovered clock of which frequency is divided in the dividing (o).

14. A phase shifter, comprising:
a phase shifting section to which an alternate current input signal is supplied, and that shifts a phase of the input signal by a prescribed angular degree;
a first multiplying section to which the input signal and a first control voltage are supplied, and that multiplies the input signal by the first control voltage;
a second multiplying section to which an output signal of the phase shifting section and a second control voltage are supplied, and that multiplies the output signal of the phase shifting section by the second control voltage; and
an adding section to which output signals of the first multiplying section and the second multiplying section are supplied, and that adds the output signal of the first multiplying section to the output signal of the second first multiplying section,
wherein the phase of the input signal is sequentially shifted with the first control voltage and the second control voltage.

15. The phase shifter according to claim 14, wherein
the phase shifting section shifts the phase of the input signal by approximately 90°.

16. The phase shifter according to claim 14, further comprising:
a low-pass filter that removes a high-frequency wave included in the output of the adding section.
